(19) United States
(12) Patent Application Publication
(10) Pub. No.: US 2025/0011972 A1
(43) Pub. Date: Jan. 9, 2025

(54) PROCESS OF AUTOMATIC CRYSTAL BAR COLLECTION

(71) Applicant: TCL ZHONGHUAN RENEWABLE ENERGY TECHNOLOGY CO., LTD., Tianjin (CN)

(72) Inventors: Jinxin YAN, Tianjin (CN); Youyi LIU, Tianjin (CN); Duoduo ZHANG, Tianjin (CN); Junyou ZHANG, Tianjin (CN); Jiafeng LU, Tianjin (CN); Lei ZHANG, Tianjin (CN); Jinlu SHI, Tianjin (CN); Xinyang TIAN, Tianjin (CN); Tao LIU, Tianjin (CN); Zhenyu ZHANG, Tianjin (CN); Zhibing SUN, Tianjin (CN); Xiaoyu LIU, Tianjin (CN); Kun WANG, Tianjin (CN)

(73) Assignee: TCL ZHONGHUAN RENEWABLE ENERGY TECHNOLOGY CO., LTD., Tianjin (CN)

(21) Appl. No.: 18/548,077

(22) PCT Filed: Jul. 31, 2023
(86) PCT No.: PCT/CN2023/110401

§ 371 Date: Aug. 26, 2023

(30) Foreign Application Priority Data
Aug. 31, 2022 (CN) 202211053823.1

(51) Int. Cl. C30B 35/00; C30B 15/30

(52) U.S. Cl. CPC C30B 35/005; C30B 15/30

(57) ABSTRACT

Disclosed is an automatic crystal collection process, including: placing a crystal collection cylinder on a movable platform, detecting a length of a single crystal bar, and selecting a descending distance of the movable platform according to the length of the single crystal bar; raising a furnace sub-chamber to an upper limit, rotating the sub-chamber to a position above the crystal collection cylinder, and lowering the single crystal bar into the crystal collection cylinder; cutting off a seed crystal when the single crystal bar is lowered to a distance, and moving the single crystal bar with the descending of the movable platform until the single crystal bar is collected completely; raising the crystal collection cylinder along with the single crystal bar therein to a target position by the movable platform after the single crystal bar is collected completely, and finishing the crystal collection process.

### CROSS-REFERENCE TO RELATED APPLICATION

The present disclosure claims priority to and the benefit of Chinese Patent Application No. 202211053823.1, filed on Aug. 31, 2022, the disclosure of which is incorporated herein by reference in its entirety.

### TECHNICAL FIELD

The present disclosure relates to the field of preparation processes of solar photovoltaic materials, and in particular relates to a process of automatic crystal collection.

### BACKGROUND

At present, the competition in the industry is increasingly intense, and an automation degree of single crystal production factories is gradually improved, from industrial Craft 2 to Craft 3.0 or 4.0.

In a single crystal pulling process in the prior art, an automatic control of an equal-diameter process is realized. However, after single crystal bars are pulled, a single crystal pulling worker is required to take out and store the single crystal bars, manually rotate a sub-chamber, lower the single crystal bars, and place a single crystal collection cylinder. Since the lengths of the single crystal bars collected are different, the single crystal collection cylinder needs to be placed at different positions. At present, the work of both picking and placing single crystal bars relies on manual operation. In this process, it is necessary for the workers to arrange a warning line, and place the crystal collection cylinder at different positions by a rope. However, a position deviation of the crystal collection cylinder may affect the taking out of the single crystal bars, and there may be a potential safety hazard and a serious time waste in the process.

### SUMMARY

The present disclosure provides a process of automatic single crystal bar collection, which effectively solves the problems that: the existing operation of both taking and placing of single crystal bars relies on human labor, the warning line needs to be arranged, the crystal collection cylinder may be placed at different positions by a rope to affect the taking out of the single crystal bars due to position deviation, and there may be a potential safety hazard and a serious time waste.

In order to solve the above technical problems, the present disclosure provides a process of automatic single crystal bar collection, which includes:
placing a crystal collection cylinder on a movable platform, determining a length of a single crystal bar, and selecting a descending distance of the movable platform according to the length of the single crystal bar;
raising a furnace sub-chamber to an upper limit, rotating the sub-chamber to a position above the crystal collection cylinder, and lowering the single crystal bar into the crystal collection cylinder;
cutting off a seed crystal when the single crystal bar is descended to a distance, and moving the single crystal bar with the descending of the movable platform until the single crystal bar is collected completely;
raising the crystal collection cylinder along with the single crystal bar therein to a target position by the movable platform after the single crystal bar is collected completely, and finishing the crystal collection process.

In some embodiment of the present disclosure, a fixing support is further disposed on the movable platform to prevent the crystal collection cylinder from moving back and forth.

In some embodiment of the present disclosure, a cylinder opening of the crystal collection cylinder has a shape with a variable diameter.

In some embodiment of the present disclosure, the diameter of the cylinder opening of the crystal collection cylinder is reduced from up to down.

In some embodiment of the present disclosure, during collecting the single crystal bar, a laser lamp disposed on a side of the furnace close to an outer channel is turned on to remind that the single crystal bar is being collected, and the laser lamp is turned off after the single crystal bar is collected completely.

In some embodiment of the present disclosure, the single crystal bar is descended into the crystal collection cylinder at a speed of 450-550 mm/min after the sub-chamber is rotated to the position above the crystal collection cylinder.

In some embodiment of the present disclosure, a weight sensor is further disposed inside the crystal collection cylinder to detect a weight of the single crystal bar entering the crystal collection cylinder; when the weight of the single crystal bar exceeds 50 kg, the single crystal bar stops descending, and the cutting of the seed crystal is carried out.

In some embodiment of the present disclosure, after the single crystal bar is collected completely, the movable platform is raised to a position where the single crystal bar is easily moved.

The above technical solutions changes the problem that the conventional single crystal pick-up process is completely dependent on human labor and cause time waste. This process is controlled by an automatic program to realize automatic lifting and rotation of the sub-chamber for single crystal bar picking, and realize automatic lifting, positioning and lowering of the crystal collection cylinder.

With the above technical solutions, it can automatically remind the workers about the single crystal collection operation in a relatively dangerous step of single crystal bar descending to ensure safety. The entire process is automated, instead of a conventional operation of using an intercom to notify an inspector to perform the single crystal collection operation.

According to the above technical solutions, after statistics, about 60 minutes may be saved in The process of automatic crystal bar collection compared with the crystal collection operation by manually placing the crystal collection cylinder, and about 5 minutes may be saved in the process of taking out the single crystal bar for detection. Therefore, about 500 minutes can be saved for a single furnace, based on the taking out of single crystal bars 8 times, and thus the production can be increased by 100 kg per month or more. The upgrade of the automatic crystal collection cylinder provides a solid foundation for the automation of the entire crystal pulling process.

### BRIEF DESCRIPTION OF THE DRAWINGS

In order to more clearly illustrate the technical solutions in the embodiments of the present disclosure, reference will now be made briefly below to the accompanying drawings required for the description of the embodiments. It will be apparent that the accompanying drawings in the following description are merely some of the embodiments of the present disclosure, and other drawings may be obtained based on these drawings to those skilled in the art without involving any inventive effort.

FIG. 1 is schematic structural view showing a device for performing a process of automatic crystal bar collection according to an embodiment of the present disclosure.

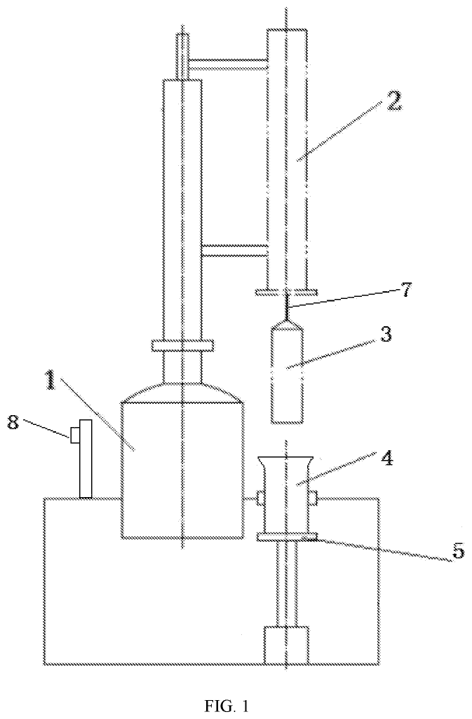

FIG. 2 is schematic structural view showing a part of a device for performing a process of automatic crystal bar collection according to an embodiment of the present disclosure.

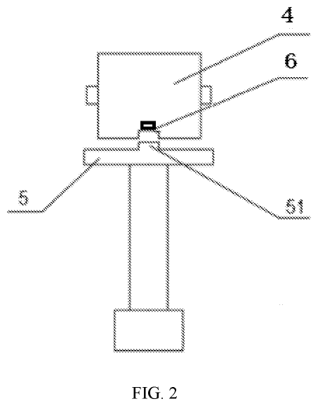

### LIST OF REFERENCE NUMBERS

1: Single crystal furnace; 2: Furnace sub-chamber; 3: Single crystal bar; 4: Crystal collection cylinder; 5: Movable platform; 51: Fixing support; 6: Weight sensor; 7: Seed crystal; 8: Laser lamp.

### DETAILED DESCRIPTION OF THE EMBODIMENTS

The present disclosure is further illustrated by the following embodiments.

In the description of embodiments of the present disclosure, it is to be understood that orientations or position relationships indicated by the terms “top”, “bottom”, and the like are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure. In the description of the present disclosure, it should be noted that the terms “arrangement” and “connection” should be understood in a broad sense, unless otherwise clearly specified and defined. For example, it can be a fixed connection, a detachable connection, or integrated connection; it can be directly connected or indirectly connected through an intermediary, it can also communicate between insides of two elements. Those ordinary skilled in the art can understand the specific meanings of the above terms in the present disclosure according to specific situations.

A process of automatic single crystal bar collection includes:

S1, placing a crystal collection cylinder 4 on a movable platform 5, determining a length of the single crystal bar 3, and selecting a descending distance of the movable platform 5 according to the length of the single crystal bar 3.

The movable platform 5 is a platform that can be raised or lowered along a length direction of the single crystal bar 3. The movable platform 5 can be controlled by an air cylinder or a motor. The crystal collection cylinder 4 can be stably raised or lowered with the movable platform 5. The crystal collection cylinder 4 is configured to accommodate the single crystal bar 3.

In some practicable embodiments, a fixing support 51 is disposed on the movable platform 5 to prevent the crystal collection cylinder 4 from moving back and forth. The fixing support 51 enables the crystal collection cylinder 4 to be fixed, so that the crystal collection cylinder 4 can be placed on the movable platform 5 without left and right or back and forth movement, thereby avoiding the single crystal bar 3 to be inclined or even broken when entering the crystal collection cylinder 4 due to misplacement of the crystal collection cylinder 4.

In some practicable embodiments, a cylinder opening of the crystal collection cylinder 4 has a shape with a variable diameter. Preferably, the diameter of the cylinder opening of the crystal collection cylinder 4 is reduced from up to down. The element with the variable diameter allows the single crystal bar 3 to enter into the crystal collection cylinder 4 even if the single crystal bar 3 is not aligned with the crystal collection cylinder 4, thereby reducing an unexpected condition due to a position deviation with respect to the crystal collection cylinder 4.

In some practicable embodiments, the length of the single crystal bar 3 can be determined and recorded by an infrared sensor, and the descending distance of the movable platform 5 can be calculated and controlled by a central system. Typically, the descending distance of the movable platform 5 is slightly smaller than the length of the single crystal bar 3.

S2, raising a furnace sub-chamber 2 to an upper limit, rotating the sub-chamber 2 to a position above the crystal collection cylinder 4, and lowering the single crystal bar 3 into the crystal collection cylinder 4.

The rotating of the sub-chamber 2 is directly controlled by a sensing device. When the sensing device senses that the sub-chamber 2 is located in a region above the crystal collection cylinder 4, the sub-chamber 2 stops rotating. Preferably, the sub-chamber 2 is rotated to a position directly above a center of the crystal collection cylinder 4.

When the sub-chamber 2 is rotated to the position above the crystal collection cylinder 4, the single crystal bar 3 is descended into the crystal collection cylinder 4 at a speed of 450-550 mm/min, preferably 480-530 mm/min, more preferably 490, 500, or 510 mm/min.

S3, cutting off a seed crystal 7 when the single crystal bar 3 is descended to a distance, and moving the single crystal bar 3 with the descending of the movable platform 5 until the single crystal is collected completely.

A weight sensor 6 is disposed inside the crystal collection cylinder 4, and is configured to detect a weight of the single crystal bar 3 entering the crystal collection cylinder 4. The weight of the single crystal bar 3 can be detected when the single crystal bar 3 is collected completely.

The distance to which the single crystal bar 3 is lowered may be different depending to different single crystal bar 3s, and there is a standard in which: the single crystal bar 3 stops descending when the weight of the single crystal bar 3 detected by the weight sensor 6 exceeds 50 kg. Meanwhile, the central system sends out a reminder that the seed crystal 7 needs to be cut off. At this time, a worker or a manipulator can perform the operation of cutting the seed crystal 7 at the front of the furnace 1.

During the process of collecting the single crystal bar 3, a laser lamp 8 disposed on a side of the furnace 1 close to an outer channel is turned on to remind the workers that the single crystal bar 3 is being collected at this time, and it is forbidden to approach. After the single crystal bar 3 is collected, the laser lamp 8 is turned off.

S4, Raising the crystal collection cylinder 4 along with the single crystal bar 3 therein to a target position by the movable platform 5 after the single crystal bar 3 is collected completely, and finishing the crystal collection process.

The whole single crystal bar 3 is collected, and transferred into the crystal collection cylinder 4 on the movable platform 5. Then, the movable platform 5 is raised to a ground position, so that the single crystal bar 3 is raised to a position where the single crystal bar 3 can be conveniently moved by an inspector. Therefore, the operation time of hooking and lashing the single crystal bar 3 by the inspector, required during taking out of the single crystal bar 3 from the furnace bottom, can be saved. For example, 7 to 10 minutes can be saved in this step for each single crystal bar 3.

The present disclosure changes a traditional process in which the single crystal bar 3 collection completely relies on manual work. According to the present disclosure, an automatic program is used for control, so as to achieve automatic raising and rotation of the sub-chamber 2 for taking out the single crystal bar 3, achieve automatic raising, positioning and lowering of the crystal collection cylinder 4, and achieve automatic reminder on the single crystal collection operation for the operators to ensure safety. The entire process according to the present disclosure is carried out automatically, instead of the use of a traditional intercom for instructing the inspector to collect the single crystal bar 3. Time of collecting the single crystal bar 3 may be counted in a background system, wherein about 60 minutes may be saved compared with the crystal collection operation by manually placing the crystal collection cylinder 4, and about 7-10 minutes may be saved in the process of taking out the single crystal bar 3 for detection. Therefore, about 500 minutes can be saved for a single furnace, based on the collection of single crystal bar 3s 8 times, and thus the production can be increased by 100 kg per month or more. The automated upgrade of the crystal collection cylinder 4 provides a solid foundation for the automation of the entire crystal pulling process, and can greatly reduce the labor intensity of employees, realize the goal of few people in the crystal pulling process, significantly reduce labor costs and achieve cost reduction and efficiency.

Several specific examples are provided below.

### Example 1

S1, placing the crystal collection cylinder 4 on the movable platform 5, determining the length of the single crystal bar 3, and selecting the descending distance of the movable platform 5 according to the length of the single crystal bar 3.

The movable platform 5 is a platform that can be raised or lowered along the length direction of the single crystal bar 3. The movable platform 5 can be controlled by the air cylinder. The crystal collection cylinder 4 can be stably raised or lowered with the movable platform 5.

The fixing support 51 is disposed on the movable platform 5 to prevent the crystal collection cylinder 4 from moving back and forth. The fixing support 51 enables the crystal collection cylinder 4 to be fixed, so that the crystal collection cylinder 4 can be placed on the movable platform 5 without left and right or back and forth movement, thereby avoiding the single crystal bar 3 to be inclined or even broken when entering the crystal collection cylinder 4 due to misplacement of the crystal collection cylinder 4.

The cylinder opening of the crystal collection cylinder 4 has the shape of the variable diameter, and the diameter of the cylinder opening of the crystal collection cylinder 4 is reduced from up to down. The element with the variable diameter allows the single crystal bar 3 to enter into the crystal collection cylinder 4 even if the single crystal bar 3 is not aligned with the crystal collection cylinder 4, thereby reducing an unexpected condition due to a position deviation with respect to the crystal collection cylinder 4.

The length of the single crystal bar 3 can be determined and recorded by the infrared sensor, and the descending distance of the movable platform 5 can be calculated and controlled by the central system.

S2, Raising the furnace sub-chamber 2 to the upper limit, rotating the sub-chamber 2 to the position above the crystal collection cylinder 4, and descending the single crystal bar 3 into the crystal collection cylinder 4.

The sub-chamber 2 is rotated to the position above the crystal collection cylinder 4.

When the sub-chamber 2 is rotated to the position above the crystal collection cylinder 4, the single crystal bar 3 is descended into the crystal collection cylinder 4 at a speed of 450 mm/min.

S3, Cutting off the seed crystal 7 when the single crystal bar 3 is descended to a distance, and moving the single crystal bar 3 with the descending of the movable platform 5 until the single crystal is collected completely;

The weight sensor 6 is disposed inside the crystal collection cylinder 4, and is configured to detect the weight of the single crystal bar 3 entering the crystal collection cylinder 4. The weight of the single crystal bar 3 can be detected when the single crystal bar 3 is collected completely.

The distance to which the single crystal bar 3 is lowered may be different depending to different single crystal bar 3s, and there is a standard in which: the single crystal bar 3 stops descending when the weight of the single crystal bar 3 detected by the weight sensor 6 exceeds 50 kg. Meanwhile, the central system sends out the reminder that the seed crystal 7 needs to be cut off. At this time, the worker can perform the operation of cutting the seed crystal 7 at the front of the furnace 1.

S4: Raising the crystal collection cylinder 4 along with the single crystal bar 3 therein to the target position by the movable platform 5 after the single crystal bar 3 is collected completely, and finishing the crystal collection process.

The single crystal bar 3 is collected completely, and transferred into the crystal collection cylinder 4 on the movable platform 5. Then, the movable platform 5 is raised to the ground position, so that the single crystal bar 3 is raised to the position where the single crystal bar 3 by the inspector can be conveniently moved. Therefore, the operation time of hooking and lashing the single crystal bar 3 by the inspector, required during collection of the single crystal bar 3 from the furnace bottom, can be saved, wherein 7 minutes can be saved in this step for each single crystal bar 3. Then, the collection of the single crystal bar 3 is finished.

### Example 2

S1, placing the crystal collection cylinder 4 on the movable platform 5, determining the length of the single crystal bar 3, and selecting the descending distance of the movable platform 5 according to the length of the single crystal bar 3.

The movable platform 5 is a platform that can be raised or lowered along the length direction of the single crystal bar 3. The movable platform 5 can be controlled by the motor. The crystal collection cylinder 4 can be stably raised or lowered with the movable platform 5.

The fixing support 51 is disposed on the movable platform 5 to prevent the crystal collection cylinder 4 from moving back and forth. The fixing support 51 enables the crystal collection cylinder 4 to be fixed, so that the crystal collection cylinder 4 can be placed on the movable platform 5 without left and right or back and forth movement, thereby avoiding the single crystal bar 3 to be inclined or even broken when entering the crystal collection cylinder 4 due to misplacement of the crystal collection cylinder 4.

The cylinder opening of the crystal collection cylinder 4 has the shape of the variable diameter, and the diameter of the cylinder opening of the crystal collection cylinder 4 is reduced from up to down. The element with the variable diameter allows the single crystal bar 3 to enter into the crystal collection cylinder 4 even if the single crystal bar 3 is not aligned with the crystal collection cylinder 4, thereby reducing an unexpected condition due to a position deviation with respect to the crystal collection cylinder 4.

The length of the single crystal bar 3 can be determined and recorded by the infrared sensor, and the descending distance of the movable platform 5 can be calculated and controlled by the central system.

S2, Raising the furnace sub-chamber 2 to the upper limit, rotating the sub-chamber 2 to the position above the crystal collection cylinder 4, and descending the single crystal bar 3 into the crystal collection cylinder 4.

The sub-chamber 2 is rotated to above directly the center of the crystal collection cylinder 4.

When the sub-chamber 2 is rotated to the position above the crystal collection cylinder 4, the single crystal bar 3 is descended into the crystal collection cylinder 4 at a speed of 500 mm/min.

S3, Cutting off the seed crystal 7 when the single crystal bar 3 is descended to a distance, and moving the single crystal bar 3 with the descending of the movable platform 5 until the single crystal is collected completely;

The weight sensor 6 is disposed inside the crystal collection cylinder 4, and is configured to detect the weight of the single crystal bar 3 entering the crystal collection cylinder 4. The weight of the single crystal bar 3 can be detected when the single crystal bar 3 is collected completely.

The distance to which the single crystal bar 3 is lowered may be different depending to different single crystal bar 3s, and there is a standard in which: the single crystal bar 3 stops descending when the weight of the single crystal bar 3 detected by the weight sensor 6 exceeds 50 kg. Meanwhile, the central system sends out the reminder that the seed crystal 7 needs to be cut off. At this time, the manipulator can perform the operation of cutting the seed crystal 7 at the front of the furnace 1.

During the process of collecting the single crystal bar 3, a laser lamp 8 disposed on a side of the furnace 1 close to an outer channel is turned on to remind the workers that the single crystal bar 3 is being collected at this time, and it is forbidden to approach. After the single crystal bar 3 is collected, the laser lamp 8 is turned off.

S4: Raising the crystal collection cylinder 4 along with the single crystal bar 3 therein to the target position by the movable platform 5 after the single crystal bar 3 is collected completely, and finishing the crystal collection process.

The single crystal bar 3 is collected completely, and transferred into the crystal collection cylinder 4 on the movable platform 5. Then, the movable platform 5 is raised to the ground position, so that the single crystal bar 3 is raised to the position where the single crystal bar 3 by the inspector can be conveniently moved. Therefore, the operation time of hooking and lashing the single crystal bar 3 by the inspector, required during collection of the single crystal bar 3 from the furnace bottom, can be saved, wherein 10 minutes can be saved in this step for each single crystal bar 3.

Although several embodiments of the present disclosure have been described in detail above, the described contents are only preferred embodiments of the present disclosure and should not be considered as limiting the scope of the present disclosure. All of modifications and improvements made in accordance with the scope of the present disclosure shall also fall within the scope defined by the following claims of present disclosure.

What is claimed is:

1. A process of automatic single crystal bar collection, comprising:
placing a crystal collection cylinder on a movable platform, determining a length of the single crystal bar, and selecting a descending distance of the movable platform according to the length of the single crystal bar;
raising a furnace sub-chamber to an upper limit, rotating the sub-chamber to a position above the crystal collection cylinder, and lowering the single crystal bar into the crystal collection cylinder;
cutting off a seed crystal when the single crystal bar is descended to a distance, and moving the single crystal bar with the descending of the movable platform until the single crystal bar is collected completely;
raising the crystal collection cylinder along with the single crystal bar therein to a target position by the movable platform after the single crystal bar is collected completely, and finishing the process of crystal bar collection.

2. The process of automatic crystal bar collection according to claim 1, wherein a fixing support is disposed on the movable platform to prevent the crystal collection cylinder from moving back and forth.

3. The process of automatic crystal bar collection according to claim 1, wherein a cylinder opening of the crystal collection cylinder has a shape with a variable diameter in a vertical direction.

4. The process of automatic crystal bar collection according to claim 2, wherein a cylinder opening of the crystal collection cylinder has a shape with a variable diameter in a vertical direction.

5. The process of automatic crystal bar collection according to claim 3, wherein the diameter of the cylinder opening of the crystal collection cylinder is reduced from up to down.

6. The process of automatic crystal bar collection according to claim 4, wherein the diameter of the cylinder opening of the crystal collection cylinder is reduced from up to down.

7. The process of automatic crystal bar collection according to claim 1, wherein during collecting the single crystal bar, a laser lamp disposed on a side of the furnace close to an outer channel is turned on to remind that the single crystal bar is being collected, and the laser lamp is turned off after the single crystal bar is collected completely.

8. The process of automatic crystal bar collection according to claim 1, wherein the single crystal bar is descended into the crystal collection cylinder at a speed of 450-550 mm/min after the sub-chamber is rotated to the position above the crystal collection cylinder.

9. The process of automatic crystal bar collection according to claim 1, wherein a weight sensor is disposed inside the crystal collection cylinder to detect a weight of the single crystal bar entering the crystal collection cylinder; when the weight of the single crystal bar exceeds 50 kg, the single crystal bar stops descending, and the cutting of the seed crystal is carried out.

10. The process of automatic crystal bar collection according to claim 8, wherein a weight sensor is disposed inside the crystal collection cylinder to detect a weight of the single crystal bar entering the crystal collection cylinder; when the weight of the single crystal bar exceeds 50 kg, the single crystal bar stops descending, and the cutting of the seed crystal is carried out.

11. The process of automatic crystal bar collection according to claim 1, wherein the movable platform is raised to a position where the single crystal bar is easily moved, after the single crystal bar is connected completely.
